(19) United States
(12) Patent Application Publication
(10) Pub. No.: US 2012/0300576 A1
(43) Pub. Date: Nov. 29, 2012

(54) PLANAR LABYRINTH MICROMIXER SYSTEMS AND METHODS

(75) Inventors: Peng Li, Southbridge, MA (US); Jeremy Cogswell, Johnston, RI (US); Mohammed Faghri, East Greenwich, RI (US)

(73) Assignee: Board of Governors for Higher Education, State of Rhode Island and Providence Plantations, Providence, RI (US)

(21) Appl. No.: 13/557,617

(22) Filed: Jul. 25, 2012

Related U.S. Application Data
(63) Continuation of application No. PCT/US2011/022529, filed on Jan. 26, 2011.
(60) Provisional application No. 61/298,278, filed on Jan. 26, 2010.

(51) Int. Cl. B01F 5/06; B81B 1/00

(52) U.S. Cl. 366/338

(57) ABSTRACT

A planar labyrinth micromixer is disclosed that includes an inlet port, a plurality of curved channels, a plurality of abrupt turns, and an outlet port. The inlet port is for receiving a plurality of input fluids to be mixed. The plurality of curved channels induce transverse Dean vortices that rotate processing streams. The plurality of abrupt turns fold laminar flow of the processing streams, shift elliptical points corresponding to centers of Dean flow regions, and disrupt flow islands. The output port is for providing the processing streams as a mixture of the plurality of input fluids.

### PRIORITY

The present application claims priority to U.S. Provisional Patent Application Ser. No. 61/298,278 filed Jan. 26, 2010, the entire disclosure of which is hereby incorporated by reference.

### GOVERNMENT SPONSORSHIP

The present invention was developed, in part, with assistance from the United States Government under National Science Foundation Grant No. 0530203. The United States government has certain rights to this invention.

### BACKGROUND

The invention generally relates to micro-mixing system, and relates in particular to systems and methods for providing rapid and efficient fluid mixing.

Rapid and efficient micro-mixing is essential to a wide variety of microfluidic systems targeted for applications in biological analysis, chemical synthesis, drug discovery, and DNA sequencing. Certain types of microfluidic mixing systems include microchannels, but in microchannels where the flow is strictly laminar, the transverse components of the flow that stir the fluids to achieve proper mixing are absent, so the mixing of species between streams depends exclusively on molecular diffusion.

Transverse flows may be generated in micro-scale by time-periodic modulation of the flow field via external electric, magnetic, thermal or acoustic energy (see, for example Micromixers—a review, by N. T. Nguyen and Z. Wu, Journal of Micromechanics and Microengineering v. 15, no. 2, pp. R1-R16 (2005); and Micromixers—a review on passive and active mixing Principles, by V. Hessel, H. Löwe and F. Schönfeld, Chemical Engineering Science v. 60, no. 8-9, pp. 2479-2501 (2005)). These approaches, termed as active mixing, have proven efficient but they are often difficult to fabricate, operate, maintain and integrate into microfluidic systems.

Passive micromixers, on the other hand, do not require external energy except for pumping and they are generally more robust and less expensive. The mechanisms employed for passive micromixing may be broadly classified into lamination and chaotic advection. In lamination micromixers, such as the split-and-recombine micromixer (see An optimised split-and-recombine micro-mixer with uniform ‘chaotic’ mixing, by F. Schönfeld, V. Hessel, and C. Hofmann, Lab on a Chip, v. 4 no. 1, pp. 65-69 (2004)) and the topologic micromixer (Topologic mixing on a microfluidic chip, by H. Chen and J. C. Meiners, Applied Physics Letter v. 84 no. 12, pp. 2193-2195 (2004)), the fluid streams are repeatedly split into multiple fluid lamellae and subsequently recombined to mimic a series of Baker's transformation (see Foundations of chaotic mixing, by S. Wiggins and J. M. Ottino, Philosophical Transactions of the Royal Society London v. A no. 362, pp. 937-970 (2004)).

The multi-lamella structure formed in this process leads to a reduction in the striation thickness so that molecular diffusion alone results in rapid mixing. In contrast to lamination, micromixers based on chaotic advection rely on transverse flows that stretch, fold and break up volumes of fluid to achieve sufficient mixing. Chaotic advection can be passively achieved in three-dimensional (3D) flow through the perturbations that are imposed by space-periodic geometries, such as the staggered herringbone grooves (see Chaotic mixer for microchannels, by A. D. Stroock, S. K. W. Dertinger, A Ajdari, I. Mezic, H A Stone and G. M. Whitesides, Science v. 295 no. 5555 pp. 647-651 (2002)) and the 3D serpentine microchannel with repeating “C-shaped” units (see Passive mixing in a three-dimensional serpentine microchannel, by R. H. Liu, M. A. Stremler, K. V. Sharp, M. G. Olsen, J. G. Santiago, R. J. Adrian, H. Aref and D. J. Beebe, Journal of Microelectromechanical Systems v. 9 no. 2, pp. 190-197 (2002)).

While both lamination and chaotic advection micromixers have demonstrated excellent mixing capabilities, the 3D flow networks associated with most of these designs require sophisticated multilayer lithography and therefore are difficult to integrate with other in-plane microfluidic components. Ultimately, it would be desirable to achieve rapid and efficient mixing with simple planar 2D geometries that can be fabricated in a single lithography step.

Efficient mixing has been successfully achieved with complex planar 2D geometries, such as the 2D meandering microchannel with perforated walls (see A fast passive and planar liquid sample micromixer, by J. Melin, G. Giménez, N. Roxhed, W. Wijngaart and G. Stemme, Lab on a Chip v. 4, no. 3 pp. 214-219 (2004)) and the planar straight channel incorporated with diamond-shaped (see A passive planar micromixer with obstructions for mixing at low Reynolds numbers, by A. A. S. Bhagat, E. T. K. Peterson, and I. Papautsky, Journal of Micromechanics and Microengineering v. 17, no. 5, pp. 1017-1024 (2007)) or pillar obstructions (see Evaluation of passive mixing behaviors in a pillar obstruction poly(dimethylsiloxane) microfluidic mixer using fluorescence microscopy, by L. Chen, G. Wang, C. Lim, G. H. Seong, J. Choo, E. K. Lee, S. H. Kang, and J. M. Song, Journal of Microfluidics and Nanofludics v. 7, no. 2 pp. 267-273 (2009)).

These patterns may effectively enhance the mixing process by either imposing a constant perturbation on the internal flowlines of the fluid or partially break-up and recombine the flow. The drawback is that using these complex geometries significantly increases the surface area of the system, which consequently increases the likelihood of fouling. The feasibility of producing chaotic advection in simple planar smooth-walled 2D microchannels has also been investigated with zigzag, rhombic, and curved mixing units (see, for example, Mixing processes in a zigzag microchannel: finite element simulations and optical study, by V. Mengeaud, J. Josserand, and H. H. Girault, Analytical Chemistry v. 74, no. 16, pp. 4279-4286 (2002); Mixing behavior of the rhombic micromixers over a wide Reynolds number range using Taguchi method and 3D numerical simulations, by C. K. Chung, T. R. Shih, T. C. Chen and B. H. Wu, Biomedical Microdevices, v. 10, no. 5, pp. 739-748 (2008); Design and evaluation of a Dean vortex-based micromixer, by P. B. Howell, Jr., D. R. Mott, J. P. Golden and F. S. Ligler, Lab on a Chip v. 4, no. 6, pp. 663-669 (2004); Helical flows and chaotic mixing in curved micro channels, by F. Jiang, K. S. Drese, S. Hardt, M. Küpper and F. Schönfeld, American Institute of Chemical Engineers Journal, v. 50, no. 9, pp. 2297-2305 (2004); and Fluid mixing in planar spiral microchannels, by A. P. Sudarsan and V. M. Ugaz, Lab on a Chip v. 6, no. 1, pp. 74-82 (2006).

The zigzag and rhombic micromixers require atypically intermediate Reynolds numbers (Re>80) to induce laminar recirculations that aid mixing. In planar curved microchannels, transverse Dean flows arising from centrifugal effects offer an attractive possibility of providing chaotic mixing. For Re˜O(10), the generated Dean flows on the cross-sectional plane are characterized by a pair of counter-rotating vortices that is symmetric with respect to the horizontal midplane of the microchannel. The reflectional symmetry is undesirable for chaotic mixing as the elliptic stream lines of Dean vortices form two islands that have been found to not mix well with the surrounding fluid. This effect becomes more pronounced for comparatively weak Dean vortices.

Thus, it is not surprising that the mixing efficiency of micromixers based on Dean flows has not been significantly enhanced at intermediately low Reynolds numbers (121 Re<10) (see for example Mixing in curved tubes, by V. Kumar, M. Aggarwal, and K. D. P. Nigam, Chemical Engineering Science v. 61, no. 17, pp. 5742-5753 (2006); and Optical sectioning for microfluidics: secondary flow and mixing in a meandering microchannel, by Y. C. Ahn, W. Jung and Z. Chen, Lab Chip v. 8, no. 1, pp. 125-133 (2008)).

For example, Dean flows at Re˜O(10) in the S-shaped microchannels are known to only oscillate the interface between two streams without achieving sufficient mixing. Although employing spiral microchannels may sustain the vortices over a longer distance, the generated secondary flow is known to be not strong enough to significantly increase the extent of mixing until high flow rates (Re>10) are reached. Multiple fluid strips, which indicate a significant increase of interfacial area for mixing, have not been observed until Re=30 with such design. To achieve more chaotic mixing, methods such as generating two additional counter-rotating Dean vortices, air bubble injection and adding a series of split-and-recombine units have been used with micromixers based on Dean flows (see also Multivortex micromixing, by A. P. Sudarsan and V. M. Ugaz, Proceedings of the National Academy of Sciences v. 103, no. 19, pp. 7228-7233 (2006)).

The Dean numbers however, (De>150) required to create additional vortices are normally out of the operation range for most real-world microfluidic systems. Introducing air bubbles or split-and-recombine features into the mixers increases either the complexity or the flow resistance of the system.

### SUMMARY

In accordance with an embodiment, the invention provides a planar labyrinth micromixer that includes an inlet port, a plurality of curved channels, a plurality of abrupt turns, and an outlet port. The inlet port is for receiving a plurality of input fluids to be mixed. The plurality of curved channels induce tranverse Dean vortices that rotate processing streams. The plurality of abrupt turns fold laminar flow of the processing streams, shift elliptical points corresponding to centers of Dean flow regions, and disrupt flow islands. The output port is for providing the processing streams as a mixture of the plurality of input fluids. In accordance with a further embodiment, the planar labyrinth micromixer further includes a circular chamber for creating expansion and contraction of the fluid to disrupt reflection symmetry of counter-rotating Dean vortices.

In accordance with another embodiment, the invention provides a planar labyrinth micromixer including an inlet port for receiving a plurality of input fluids to be mixed, a labyrinth portion, and an output port for providing a mixture of the plurality of input fluids. The labyrinth portion includes a plurality of alternating curved channels and abrupt turns, as well as a central circular chamber.

In accordance with a further embodiment, the invention provides a method of mixing a plurality of fluids. The method includes the steps of: receiving the plurality of input fluids to be mixed; inducing transverse Dean vortices in a plurality of curved channels that rotate processing streams; folding laminar flow of the processing streams in a plurality of abrupt turns that shift elliptical points corresponding to centers of Dean flow regions; creating expansion and contraction of the fluid in a circular chamber to disrupt reflection symmetry of counter-rotating Dean vortices; and providing the processing streams as a mixture of the plurality of input fluids.

In accordance with a further embodiment, the invention provides a planar micromixer that includes an inlet port for receiving a plurality of input fluids to be mixed, a plurality of curved channels for inducing transverse Dean vortices that rotate processing streams, a plurality of abrupt turns that fold laminar flow of the processing streams, and an output port for providing a mixture of the plurality of input fluids. The plurality of curved channels includes a first curved channel and a second curved channel, and at least two abrupt portions are intermediate the first curved channel and the second curved channel.

### BRIEF DESCRIPTION OF THE DRAWINGS

The following description may be further understood with reference to the accompanying drawings in which:

FIGS. 1A-1C show illustrative diagrammatic views of S shaped mixing units for comparison in accordance with an embodiment of the invention;

FIG. 2 shows illustrative diagrammatic views of numerical simulation results of mixing patterns of fluid at different cross sections for the SMU, SMU90², and SMU180 mixing units;

FIG. 3 shows illustrative diagrammatic views of numerical simulation results of cross-sectional mixing patterns of fluid after 2, 3, 4, 5, 7, 8, and 10 complete mixing units for each of the SMU, SMU90² and SMU180 mixing units;

FIG. 4 shows an illustrative graphical representation of the standard deviation of the concentration distribution as a function of downstream position for the SMU, SMU90² and SMU180 mixing units;

FIG. 5 shows an illustrative diagrammatic view of a planar labyrinth micromixer in accordance with another embodiment of the invention;

FIG. 6 shows an illustrative photographic representation of a micromixer in accordance with an embodiment of the invention fabricated in poly(dimethylsiloxane);

FIG. 7 shows illustrative epifluorescence images of mixing patterns of fluorescein isothiocyanate solution and water in accordance with an embodiment of the invention;

FIG. 8 shows illustrative graphical representations of profiles of fluorescein isothiocyanate concentration across a flow channel at various window locations in accordance with an embodiment of the invention;

FIG. 9 shows an illustrative diagrammatic view of a planar serpentine micromixer for comparison with a mixing unit of the invention;

FIG. 10 shows an illustrative graphical representation of downstream distance as a function of the Reynolds and Péclet numbers for a planar serpentine micromixer and for a planar labyrinth micromixer in accordance with an embodiment of the invention;

FIG. 11 shows an illustrative graphical representation of standard deviation as a function of downstream distance in the planar serpentine micromixer of FIG. 9; and

FIG. 12 shows an illustrative graphical representation of standard deviation as a function of downstream distance in the planar labyrinth micromixer of FIG. 5.

The drawings are shown for illustrative purposes only.

### DETAILED DESCRIPTION

The invention provides an improvement in the efficiency of Dean vortex-based mixers by only employing smooth-walled simple two-dimensional (2D) geometries without split-and-recombine features. Numerical simulation results reveal that the symmetries of Dean flows in known S-shaped mixers can be broken up by adding a simple 180° turn between two consecutive curved channels. A planar labyrinth micromixer that is composed of multiple such mixing units is designed for improved mixing. The mixer is fabricated in a single soft lithography step and the labyrinth has a footprint of 7.32 mm×7.32 mm.

Experiments using fluorescein isothiocyanate solutions and deionized water demonstrate that the design achieves fast and uniform mixing within 9.8 s to 32 ms for Reynolds numbers (Re) between 2.5 and 30. For the first time, multiple fluid bands are observed at Re=5 in a simple 2D microchannel design without using obstructions or split-and-recombine features. An inverse relationship between mixing length and mass transfer Péclet number (Pe) is observed. Due to the simple planar structure, the micromixer may be easily integrated into lab-on-a-chip devices where passive mixing is needed.

The use of such 2D micromixers will significantly reduce fabrication complexity, undesirable fouling, and flow resistance. The fluid mixing in two proposed mixing geometries were investigated and compared with an S-shaped design by numerical simulation. The most efficient geometry was then used as the basic mixing unit to construct a compact planar micromixer. Finally, the performance of the micromixer was experimentally studied and compared against a planar serpentine micromixer (PSM) over Reynolds numbers between 2.5 and 30.

In Dean vortex-based mixers, mixing is achieved by transverse Dean flows that arise in the vertical plane of curved channels due to centrifugal effects. Curved channels are the basic mixing elements for Dean vortex-based mixers. Dean vortex-based mixers employing recurring right-handed (R) and left-handed (L) curved channels have been found to have failed to create sufficient mixing at Re˜O(10). This is believed to be because the arrangement of mixing elements in the R-L-R-L-R sequence (where R is radius and L is length) only undulates the interface between two fluids. Also, having multiple such repeating elements will not eliminate unmixed regions (e.g. islands). If geometries capable of breaking this sequence are added between consecutive mixing elements, it is expected that improved mixing may be achieved from a systematic destruction of flow symmetries.

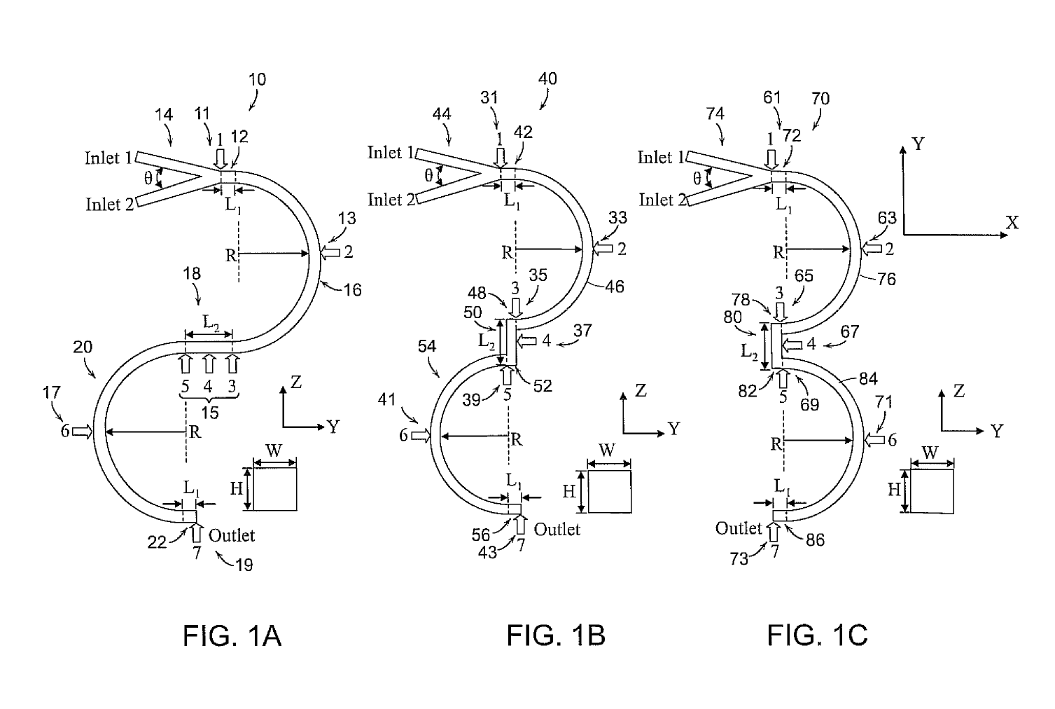

Two basic mixing units were designed to explore the possibility of breaking up the R-L-R-L-R sequence in the S-shaped mixers. Also, an S-shaped mixing unit (SMU) consisting of a Y-junction, two opposite semicircles, two short straight channels, and one long connecting channel was designed to provide a baseline for comparison. For a reference, FIG. 1A shows, in particular, an S-shape mixing structure 10 that includes a first length section 12 proximate an inlet portion 14 (providing inlets 1 and 2), a curved radial section 16, another length section 18, another curved radial section 20 and a final outlet length section 22.

FIG. 1B shows a mixing structure 40 that includes a first length section 42 proximate an inlet portion 44 (providing inlets 1 and 2), a curved radial section 46, a set of three length sections 48, 50, 52 forming two right angles, another curved radial section 54 and a final outlet length section 56. In this design, the long connecting channel (intermediate the curved portions) was used to form two 90° turns between the two semicircles as shown. FIG. 1C shows a mixing structure 70 that includes a first length section 72 proximate an inlet portion 74 (providing inlets 1 and 2), a curved radial section 76, a set of three length sections 78, 80, 82 forming two right angles in a U-shape, a reverse curved radial section 84 and a final outlet length section 86. In the design of FIG. 1C, the long connecting channel is therefore used to create a 180° turn between the two semicircles.

The angle of the Y-junction (θ), the radius of the curved channel (R), the length of the short channel (L1), the length of the connecting channel (L2), the width of the channel cross-section (W), and the channel height (H) are all kept constant for three designs. The dimensions are as follows: θ=30°, R=1.6 mm, L1=0.22 mm, L2=1.0 mm, W=0.22 mm, and H=0.267 mm. The structures 10, 40 and 70 of FIGS. 1A, 1B and 1C are referred to herein as S-shaped mixing unit (SMU), S-shaped mixing unit with two 90° turns (SMU90²), and S-shaped mixing unit with a 180° turn (SMU180).

To analyze the flow and mixing in the three different mixing units, a numerical simulation was performed (see Mixing processes in a zigzag microchannel: finite element simulations and optical study, by V. Mengeaud, J. Josserand, and H. H. Girault, Analytical Chemistry v. 74, no. 16, pp. 4279-4286 (2002)) using the commercial code, FLUENT 6.3.26. Based on the finite volume method, the FLUENT 6.3.26 solved the continuity equation and the Navier-Stokes equations in the case of an incompressible flow and a steady-state condition. The concentration distribution of species was obtained by solving the diffusion-convection equation. Gambit 2.2.30 was used to create 3D hexahedral meshes for the full model. The space was discretized with the second-order upwind scheme. The velocity and pressure fields were solved by using the SIMPLEC (Semi-Implicit Method for Pressure Linked Equations Consistent) algorithm. Constant normal velocity at the two inlets and zero static pressure at the outlet were assigned as the boundary conditions. The solutions were considered as converged when the adjacent relative error was less than 10⁻⁵. The physical properties of water were chosen as those of the working fluid. The diffusion coefficient of a solute in water was set to 6.4×10⁻¹⁰ m²/s to match the diffusion coefficient of fluorescein isothiocyanate (FITC). The grid independency was tested through verifying the results with various control volume sizes. The test indicated that the critical control volume has a transverse width of 10 μm, a lateral width of 5.5 μm, and a height of 4.5 μm, which corresponds to 2,496,000 cells for the full model.

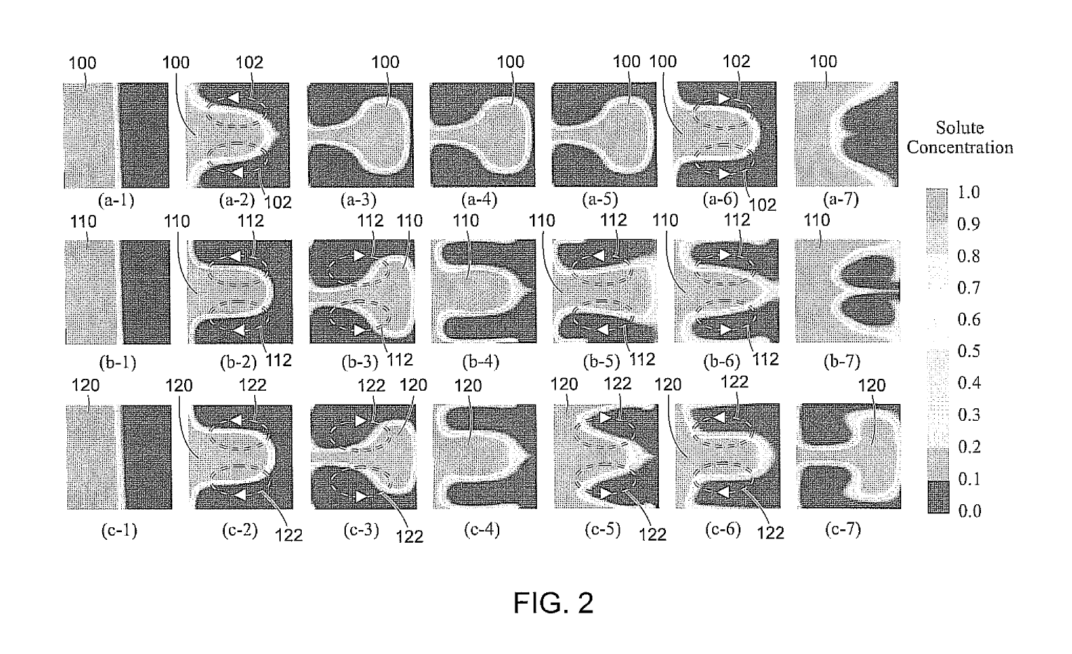

FIG. 2 shows illustrative diagrammatic views of numerical simulation results of mixing patterns of fluid at different cross sections for SMU (a-1 to a-7), SMU90² (b-1 to b-7), and SMU180 (c-1 to c-7) at Re=30. The cross-sectional images were captured by viewing against the flow direction. The solute stream (as shown at 100) is injected through inlet 2. The arrows indicate the rotational directions of the secondary flows.

The images at a-1 through 1-7 were generated for location s 1-7 (shown at 11, 13, 15, 17 and 19) of the structure 10 in FIG. 1A. As shown in at a-1 and a-7, the two mixing elements in the SMU, the interface is approximately brought back to its original position (from frame a-1 to a-7). Because of the reflection symmetry of Dean vortices, the inversion of the channel curvature in the second mixing element only inverts the rotation direction of the vortices (as indicated by the arrows in frame a-2 and a-6). Numerical analysis of the concentration contour shows that only 9.4% mixing is achieved (as discussed further below). The rotational forces that are imposed on the streams in the top half vertical plane of the SMU have a sequence of counterclockwise (CCW) and then clockwise (CW). This simulation result is in accordance with other reported experimental and numerical data in the literature.

In the SMU90² mixer (as shown in frames b-1 to b7 for location s 1-7 as shown at 31, 33, 35, 37, 39, 41 and 43) as the two streams are traveling along the first curved channel, centrifugal forces pull the solute stream (indicated at 110) that is on the left side of the image to the right (frame b-2 to b-3). As the fluid experiences the first 90° turning, the stream at the inner corner accelerates and the stream at the outer corner decelerates. This induced momentum imbalance creates rotational forces (as shown at 112) so that the solute stream is brought back to the left (frame b-4). After the next inversed 90° turn, the rotational direction is again alternated. More solute is observed at the right side of the frame b-5. In the following oppositely curved channel, the interface is almost brought back to its original position as it is in the SMU. The rotational forces that are imposed on the streams in the top half vertical plane of the SMU902 have a sequence of CCW-CW-CCW-CW. Although adding two extra opposite rotations improves the mixing to 14.6% (again, as discussed further below), this design essentially has the same sequence as that of SMU and thus fails to alternate the stream positions.

In the SMU180 mixer (as shown in frames c-1 to c7 for location s 1-7 as shown at 61, 63, 65, 67, 69, 71 and 73) the mixing processes are the same as those in the SMU90² until cross section 4. By adding the 180° turn however, the rotational forces (as shown at 122) in the SMU180 follow a sequence of CCW-CW-CW-CCW, which breaks up the sequence of CCW-CW-CCW-CW in the SMU and SMU90². After flowing through the SMU180, the two streams almost completely switch position, which leads to 16.4% mixing (again, as further discussed below) of the solute stream as shown at 120. This complete position switching is especially favorable for achieving efficient and uniform mixing because it can eliminate unmixed regions and tubes. To further test the efficiency of these designs, three micromixer models were constructed by using the above three different mixing units (MUs). Each micromixer consisted of ten successive in-line MUs of the same type.

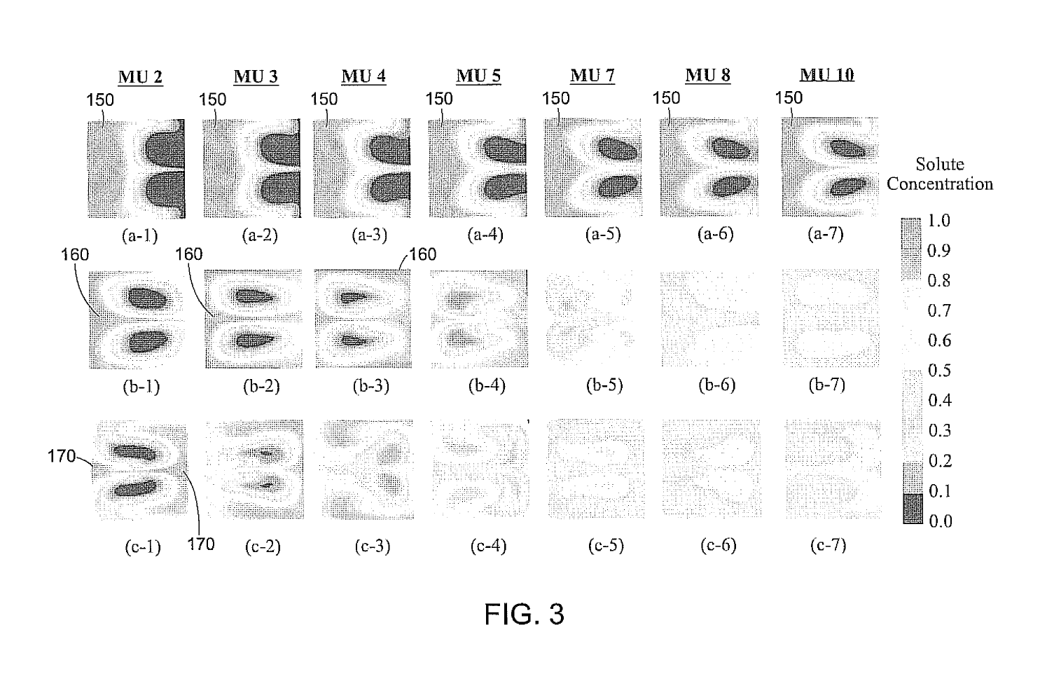

FIG. 3 shows mathematical simulation results of cross-sectional mixing patterns of fluid after 2, 3, 4, 5, 7, 8, and 10 complete mixing units in an SMU (frames a-1 through a-7), in an SMU90² (frames b-1 through b-7) and in an SMU180 (frames c-1 through c-7) at Re=30. The cross-sectional images were captured by viewing against the flow direction. The solute stream (indicated 150, 160 and 170) is injected through inlet 2.

As shown in frames a-1 through a-7 of FIG. 3, the positions of the two streams almost remain the same at the exit of each mixing unit (MU) in the micromixer constructed by using the SMU. Increasing the interface between two streams by stretching is the only mechanism to enhance mixing. In the micromixer constructed by using the SMU90² (shown at frames b-1 through b-7), although improved mixing is observed due to the extra rotational forces from the two 90′ turns, recurring mixing patterns containing unmixed “islands” can still be seen at the exit of each MU (from b-1 to b-4). In the micromixer constructed by using the SMU180 (frames c-1 through c-7), the interface between two streams is clearly distorted due to a complete position switching of the two streams. Meanwhile, the unmixed regions (“islands”) are also broken up from the position shift of the centers of the Dean vortices (from c-1 to c-2 to c-3). The SMU180 was therefore selected as the basic building block to design the micromixer in accordance with embodiments of the present invention.

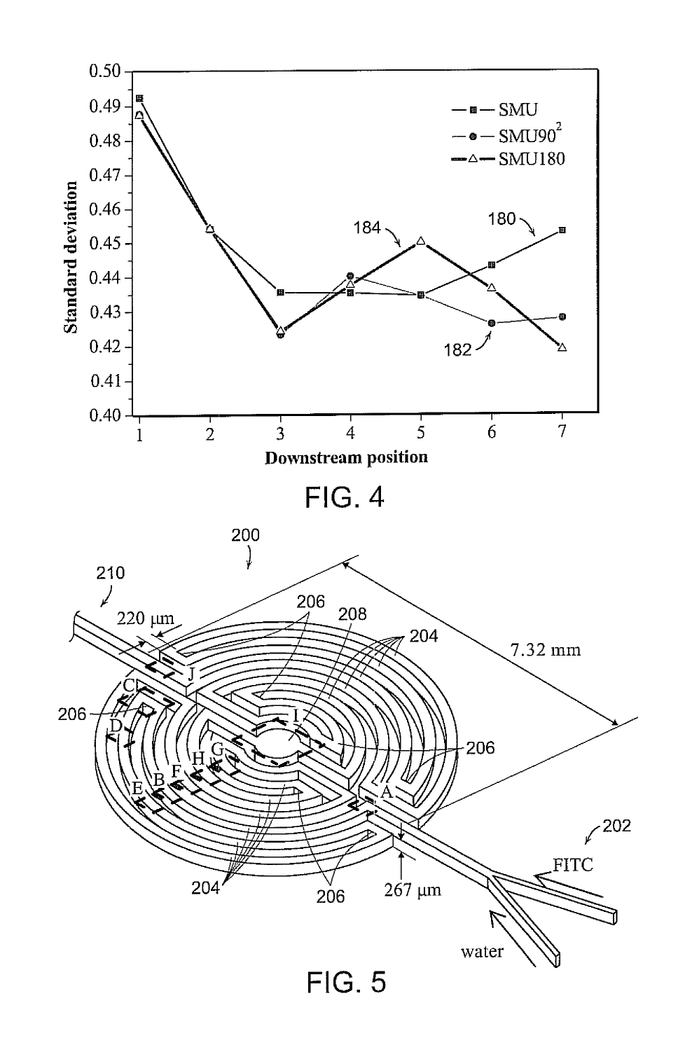

FIG. 4 shows at 180, 182 and 184, the standard deviation of the concentration as a function of downstream positions for the SMU, SMU90² and SMU180 mixing units discussed above, confirming that the SMU180 system provides improved mixing at the outlet. The percentage of mixing is calculated by using (0.5-σ)/0.5×100%, where σ is the standard deviation of the concentration at a numbered cross-sectional position. The value σ is directly acquired from FLUENT by performing surface integration over the concentration field. While a mixer with successive in-line SMU180 has shown to work effectively, the footprint of such design is too large for lab-on-a-chip devices. The percentage of mixing is calculated by using

The present invention involves the design of a planar labyrinth micromixer (PLM) consisting of multiple SMU180 that are compactly arranged within a confined circular area. When fluid is directed through the labyrinth under pressure-driven flow, the recurring arrangement of SMUI80 continuously rotates the fluid, distorts the interface between two streams repeatedly, and breaks up unmixed regions due to a complete position switching of the two streams.

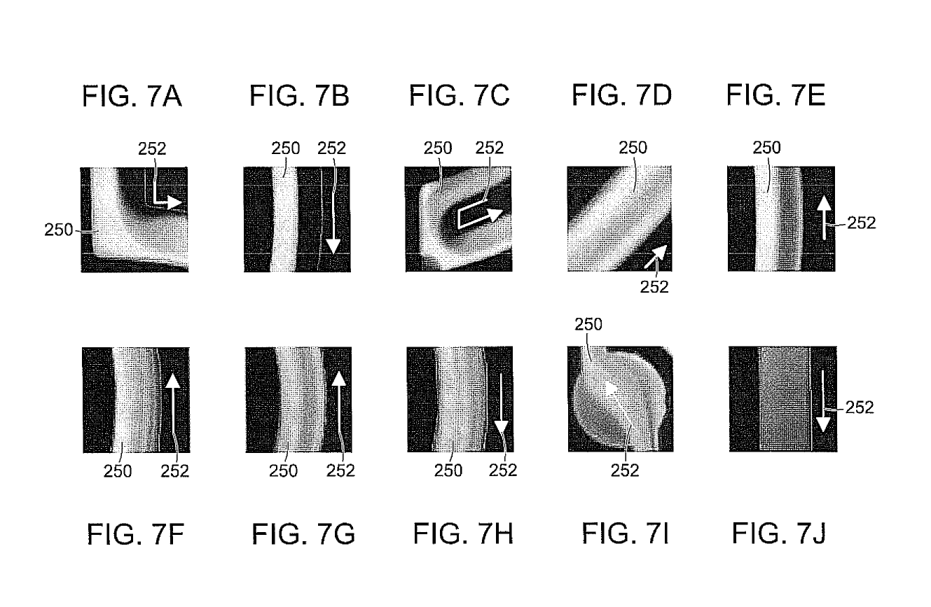

As shown in FIG. 5, the planar labyrinth micromixer (PLM) 200 constructed in accordance with another embodiment of the invention includes an inlet section 202 that includes at least two inlet channels joined in a 30° Y-junction, a 2 mm straight channel and the labyrinth. The labyrinth includes a plurality of curved channels 204 that induce transverse Dean vertices that rotate the stream, and a plurality of abrupt turns 206 that fold the laminar flow repeatedly and shift the elliptic points corresponding to the centers of the Dean cells and break up any islands. The micromixer 200 also includes at least one circular chamber 208 that creates expansion and contraction of the fluid to disrupt reflection symmetry of any counter-rotating Dean vertices. The viewing windows along the microchannels are labeled as A to J as shown in FIG. 5 and discussed below with reference to FIG. 7.

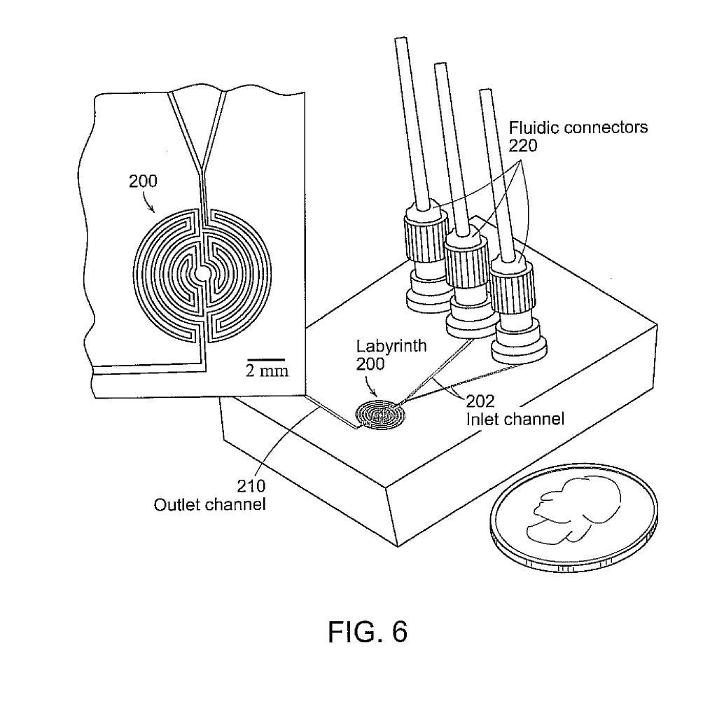

All channels are less than about 300 μm wide and less than about 300 μm deep (e.g., 220 μm wide and 267 μm deep) and the spacing between two adjacent channels is also less than less than about 300 μm (e.g., 240 μm). The labyrinth has a footprint of less than about 8 mm by 8 mm (e.g., 7.32 mm×7.32 mm). The microfluidic channels were fabricated by a single-step replication molding of poly(dimethylsiloxane) (PDMS) (Sylgard 184, Dow Corning, Midland, Mich.) from a master mold. The master molds were patterned on silicon wafers using SU-8 2050 (MicroChem Corp., Newton, Mass.) via a standard procedure. Polyetheretherketone (PEEK) fluidic connectors (Nanoport Assemblies™, Upchurch Scientific, Oak Harbor, Wash.) comprising a nut and a hollow screw were used to provide inlets and outlets for the fluids. PEEK tubings were inserted into the connectors to connect the microfluidic chip to the external fluid source. FIG. 6 shows a PLM fabricated from PDMS that is coupled to fluidic connectors as shown at 220, two of which convey fluid to the mixer and the third of which carries the mixed fluid. In addition, a PSM was also fabricated to compare with the mixing efficiency of the PLM design. The overall length, the height, and the width of the channels in the PSM are consistent with those of the PLM (as discussed further below).

To demonstrate mixing of two aqueous streams, one of which was labeled with 3 μM FITC (Pierce Biotechnology, Inc., Rockford, Ill.), the chip was anchored on a microscope glass slide and then mounted on an epifluorescence microscope (ZEISS Axioplan 2, Carl Zeiss Microlmaging, Inc., Thornwood, N.Y.). The fluorescence images were captured by a high-resolution color digital camera (ZEISS AxioCam) with a FITC filter set and a 5× objective (Plan Neofluar, numerical aperture=0.15). The degree of mixing was quantified by measuring the standard deviation (σ) of the intensity distribution over each captured image,

$$σ = \sqrt{\frac{1}{N} {\sum }_{i = 1}^{N} {( {I}_{i} - \overline{I} )}^{2}}$$

where Ii is the grayscale value (between 0 and 1) of a pixel, I is the average grayscale value over all the pixels in the image, and N is the number of pixels in the image. The grayscale values of the two fluids were normalized to be 0 for water and 1 for FITC. So the value of σ is 0.5 for two completely unmixed streams and is 0 for completely mixed streams. Flow rates were controlled by using a programmable multichannel syringe pump (Guilfoyle, Inc., Belmont, Mass.).

FIG. 7 shows epifluorescence images of the mixing patterns of FITC solution and water at a Reynolds number of 5 at each of the viewing windows A through J of FIG. 5. The images were taken with the Y junction on the top and the inlet for FITC on the left. The FITC concentration is shown at 250, and arrows 252 indicate the flow directions in each image.

Initially, the two streams are combined at the Y-junction and continue to maintain one distinct interface in the straight channel. At the first 90° turn (window A), the interface between the two fluids is substantially deflected and the water stream partially breaks into the FITC stream due to inertial effects. As the two streams enter in the first curved channel (from window A to B), centrifugal forces pull the deflected FITC stream that is closer to the outer wall radially back towards the inner wall. Then, it is swept towards the outer wall (from window B to C). Simultaneously, the water stream that is closer to the outer wall moves inwards.

At the 180° turn (window C), the interface between the two streams is significantly distorted due to a sudden reverse in the pressure gradient in response to the change of the flow direction. The water stream is shifted to the center of the second curved channel after the 180° turn, resulting in two interfaces (window D). In contrast to the mixing in the S-shaped microchannels, where the inversion of the channel curvature only brings back the interface to its original position, the design of FIG. 4 breaks up the symmetrical sequence of using recurring R-L-R-L curves by adding a 180° turn between two consecutive curved channels. As the above process successively repeats further downstream, the synergistic effect of rotation and folding continuously splits and redirects the fluid streams and more interfaces are formed (window F, G, and H).

The formation of multiple bands creates a greater interfacial area for mass transfer and diminishing striation thickness, which means increased concentration gradients and mass flux. These multiple fluid bands, which were typically seen at high flow rates (Re>30) in previously reported Dean vortex-based micromixers (see Design and evaluation of a Dean vortex-based micromixer, by P. B. Howell, Jr., D. R. Mott, J. P. Golden and F. S. Ligler, Lab on a Chip, v. 4, no. 6, pp. 663-669 (2004)), are observed at Re=5 for the first time with simple 2D microchannels. The circular chamber located at the center of the labyrinth (window I) expands and then contracts the flow to further break up the symmetric pattern of Dean vortices. Beyond a critical Reynolds number (Re˜10), an expansion vortex begin to be generated inside the circular chamber and the vortex continue to grow with the increase of Re. This expansion vortex may play an important role in accelerating interspecies transport. At the exit of the PLM (window J), the liquid appears uniformly green.

As the FITC flows therefore, through the curved channels, induced Dean vortices rotate the streams (see the images at windows B, D, E, F, G, H). As the FITC flows through the abrupt turns, the laminar is folded repeatedly, shifting the elliptic points corresponding to the centers of the Dean cells and breaking up the islands (see the images at windows A and C). The circular chamber in the center of the labyrinth creates an expansion and a contraction of the fluid that further disrupts the reflection symmetry of the two counter-rotating Dean vortices (see the image at window I). The concentration of the FITC solution is dispersed upon exiting the outlet as shown at window J.

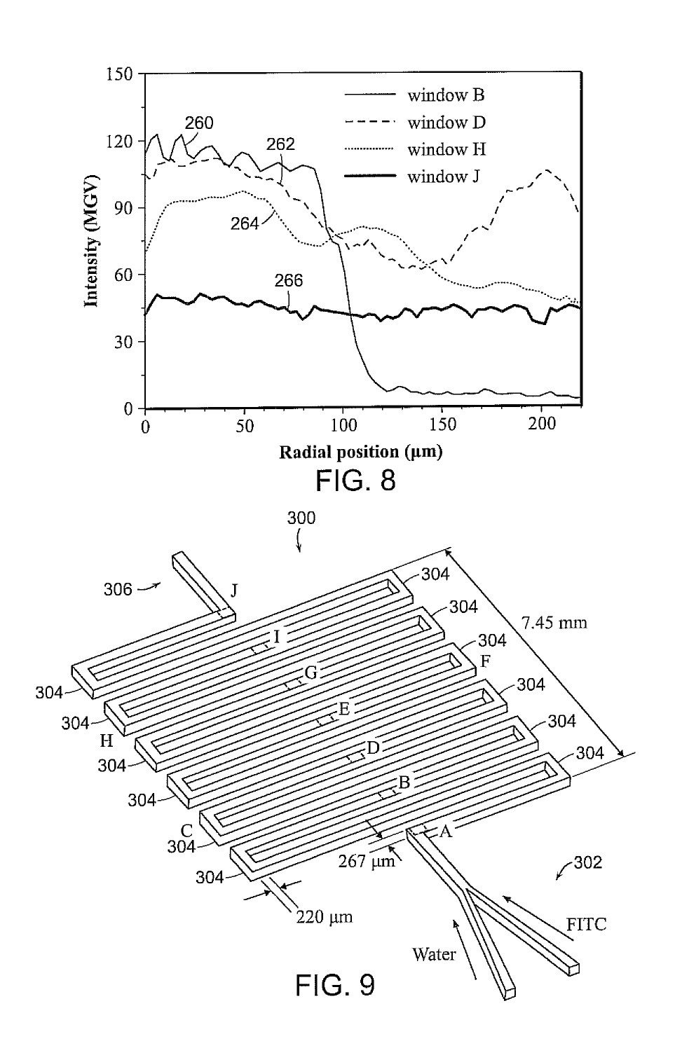

FIG. 8 shows at 260, 262, 264 and 266 profiles of FITC concentration across the flow channel at viewing window B, D, H and J. The fluorescence intensity plots were obtained by scanning the central line across the channel cross-section within each viewing window. As shown in FIG. 8, the pixel intensity across the channel changes from a step function (shown at 260) to a constant line (shown at 266), indicating that complete mixing is achieved. With the current design, fluorescence imaging shows that the mixing is enhanced above a critical Re of˜2.5 at which the folding strength of the abrupt turns becomes significant to break up the symmetries of Dean flows. Below this critical Re, there is insufficient inertial driving force and the mixing is dominated by molecular diffusion. To quantify the performance of the PLM and the PSM, fluorescence images of the mixing fluid streams were captured at various positions of the mixer at Reynolds numbers ranging from 2.5 to 30.

For comparison, FIG. 9 shows a planar serpentine micromixer (PSM) 300 that includes an inlet portion 302 (for receiving water and FITC as shown), a series of abrupt turns 304 and an outlet portion 306, but no curved channels or circular chamber.

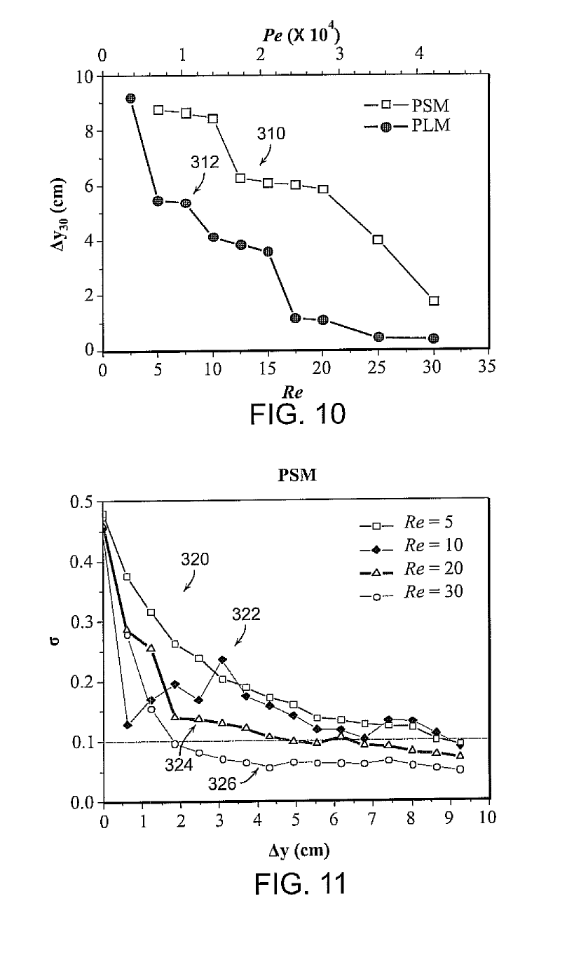

FIG. 10 shows at 310 and 312 plots of the Δy80 value as a function of the Reynolds (Re), and Péclet numbers (Pe was calculated by using D=6.4×10⁻¹⁰ m²/s for FITC) for the planar serpentine micromixer (PSM) of FIG. 9, and for the planar labyrinth micromixer (PLM) of FIG. 5 respectively. As shown, the downstream distance required for achieving 80% mixing or σ=0.1 (Δy80) is 5.5 cm for Re=5 and decreases with Pe with the PLM mixing unit This inverse relationship between mixing length and Pe is superior to the logarithmic dependence of mixing length on Pe in chaotic mixers. The time to achieve 80% mixing is 9.8 s for Re=2.5 and 32 ms for Re=30.

In contrast to the PLM, the required mixing length to achieve 80% in the PSM is 8.75 cm for Re=5. The corresponding time to achieve 80% mixing is 4.7 s for Re=5 and 153 ms for Re=30 respectively. The PSM cannot achieve 80% mixing for Re=2.5, showing the PLM is especially superior at lower Reynolds numbers. The PLM is 38% and 79% more efficient than the PSM at Re=5 and Re=30. It is noted that the mixing length in a simple microchannel would be Δym˜Pe×w=220 cm and the mixing time would be τm˜w2/D=76 s, where w is the width of the microchannel.

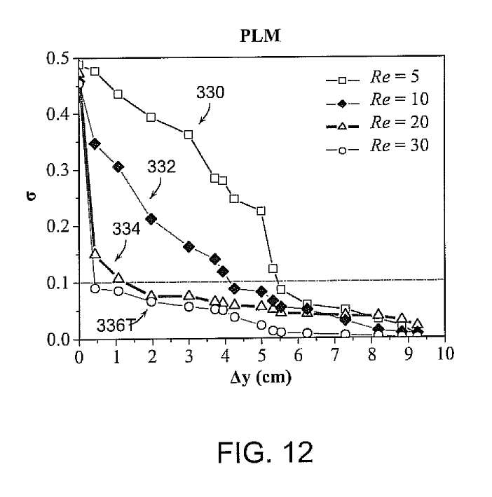

FIG. 11 shows at 320, 322, 324 and 326 plots of the standard deviation, σ, of the intensity distribution as a function of downstream distance, Δy, in the PSM for Reynolds Re=5, Re=10, Re=20 and Re-30 respectively. The horizontal dashed line (at σ=0.1) indicates the value of a used to evaluate Δy80, the downstream distance required for 80% mixing. FIG. 12 shows at 330. 332, 334 and 336 plots of the standard deviation, σ, of the intensity distribution as a function of downstream distance, Δy, in the PLM for Reynolds Re=5, Re=10, Re=20 and Re=30 respectively. Again, the horizontal dashed line (at σ=0.1) indicates the value of a used to evaluate Δy80, the downstream distance required for 80% mixing. The results indicate that the unmixed volume decreases with channel length. For this system, the molecular diffusivity of FITC (D) equals to 6.4×10⁻¹⁰ m²/s and Péclet numbers (Pe) are in the order of 10⁴.

Table 1 below shows comparisons of Δy80 and Δτ80 between the PSM and the PLM at various Reynolds numbers where Δy₈₀ is the downstream distance to achieve 80% mixing, and Δτ₈₀ is the time to achieve 80% mixing.

TABLE 1

| | Δy₈₀ | Δτ₈₀ | Δy₈₀ | Δτ₈₀ | Percentage |
|---|---|---|---|---|---|
| | PSM | PSM | PLM | PLM | of Efficiency |
| Re | (mm) | (sec) | (mm) | (sec) | Improvement |
| 2.5 | — | — | 92.03 | 9.834 | — |
| 5 | 87.48 | 4.674 | 54.53 | 2.914 | 37.7% |
| 7.5 | 86.33 | 3.075 | 53.58 | 1.909 | 37.8% |
| 10 | 84.26 | 2.251 | 41.19 | 1.100 | 51.1% |
| 13 | 62.45 | 1.335 | 38.26 | 0.818 | 38.7% |
| 15 | 60.74 | 1.082 | 35.76 | 0.637 | 41.1% |
| 18 | 59.79 | 0.913 | 11.36 | 0.173 | 81.0% |
| 20 | 58.22 | 0.778 | 10.59 | 0.141 | 81.8% |
| 25 | 39.80 | 0.425 | 4.15 | 0.044 | 89.6% |
| 30 | 17.19 | 0.153 | 3.65 | 0.032 | 78.8% |

The far right column of Table 1 shows how much more efficient the PLM is over the PSM. The percentage of efficiency improvement is calculated by using (Δy₈₀, PSM-Δy₈₀, PLM)/Δy₈₀, PSM×100%.

The invention recognizes that the symmetries of Dean flows in the S-shaped mixers may be broken up by adding a simple 180° turn between two consecutive curved channels. In accordance with an embodiment, therefore, the invention provides a planar labyrinth geometry that employs such recurring mixing units in a compact fashion. Rapid mixing may be passively achieved with the planar labyrinth microchannel design at intermediately low Reynolds numbers (2.5<Re<30). Compared to a PSM, the design results in 38% and 79% improvements on the mixing efficiency at Re=5 and Re=30 respectively. While the mixing principle behind the design is independent of the chosen microfluidic fabrication technology, it has been shown that the planar labyrinth geometry may be easily constructed in a single soft lithography step. The PLM micromixers of the invention are suitable for use in many lab-on-a-chip systems that require in-plane passive micromixers.

Those skilled in the art will appreciate that numerous modifications and variations may be made to the above disclosed embodiments without departing from the spirit or scope of the present invention.

What is claimed is:

1. A planar labyrinth micromixer comprising:
an inlet port for receiving a plurality of input fluids to be mixed;
a plurality of curved channels for inducing transverse Dean vortices that rotate processing streams;
a plurality of abrupt turns that fold laminar flow of the processing streams, shift elliptical points corresponding to centers of Dean flow regions, and disrupt flow islands; and
an output port for providing the processing streams as a mixture of the plurality of input fluids.

2. The planar labyrinth micromixer as claimed in claim 1, wherein said planar labyrinth micromixer further includes a circular chamber for creating expansion and contraction of the fluid to disrupt reflection symmetry of counter-rotating Dean vortices.

3. The planar labyrinth micromixer as claimed in claim 1, wherein said plurality of abrupt turns alternate with the plurality of curved channels.

4. The planar labyrinth micromixer as claimed in claim 1, wherein said planar labyrinth micromixer has a size of less than about 8 mm by 8 mm.

5. The planar labyrinth micromixer as claimed in claim 1, wherein said curved channels are less than about 300 μm wide and less than about 300 μm deep.

6. The planar labyrinth micromixer as claimed in claim 1, wherein said planar labyrinth micromixer is formed of poly(dimethylsiloxane).

7. The planar labyrinth micromixer as claimed in claim 1, wherein said plurality of abrupt turns each provide about a 180 degree change in direction.

8. A planar labyrinth micromixer comprising an inlet port for receiving a plurality of input fluids to be mixed, a labyrinth portion, and an output port for providing a mixture of the plurality of input fluids, wherein said labyrinth portion includes a plurality of alternating curved channels and abrupt turns, as well as a central circular chamber.

9. The planar labyrinth micromixer as claimed in claim 8, wherein said plurality of abrupt turns each provide about a 180 degree change in direction.

10. The planar labyrinth micromixer as claimed in claim 8, wherein said planar labyrinth micromixer has a size of less than about 8 mm by 8 mm.

11. The planar labyrinth micromixer as claimed in claim 8, wherein said curved channels are less than about 300 μm wide and less than about 300 μm deep.

12. The planar labyrinth micromixer as claimed in claim 8, wherein said curved channels are spaced from one another by a distance of less than about 300 μm.

13. The planar labyrinth micromixer as claimed in claim 8, wherein said planar labyrinth micromixer is formed of poly(dimethylsiloxane).

14. A method of mixing a plurality of fluids, said method comprising the steps of:
receiving the plurality of input fluids to be mixed;
inducing transverse Dean vortices in a plurality of curved channels that rotate processing streams;
folding laminar flow of the processing streams in a plurality of abrupt turns that shift elliptical points corresponding to centers of Dean flow regions;
creating expansion and contraction of the fluid in a circular chamber to disrupt reflection symmetry of counter-rotating Dean vortices; and
providing the processing streams as a mixture of the plurality of input fluids.

15. The method as claimed in claim 14, wherein said steps of inducing transverse Dean vortices and folding laminar flow of the processing streams alternate and are repeated a plurality of times.

16. The method as claimed in claim 14, wherein said step of folding laminar flow involves changing the direction of the processing streams by 180 degrees.

17. The method as claimed in claim 14, wherein said method is performed on a planar labyrinth micromixer having a size of less than about 8 mm by 8 mm.

18. The method as claimed in claim 14, wherein said curved channels are less than about 300 μm wide and less than about 300 μm deep.

19. The method as claimed in claim 14, wherein said curved channels are spaced from one another by a distance of less than about 300 μm.

20. The method as claimed in claim 14, wherein said method is performed on a planar labyrinth micromixer that is formed of poly(dimethylsiloxane).

21. A planar micromixer comprising an inlet port for receiving a plurality of input fluids to be mixed, a plurality of curved channels for inducing transverse Dean vortices that rotate processing streams, a plurality of abrupt turns that fold laminar flow of the processing streams, and an output port for providing a mixture of the plurality of input fluids, wherein said plurality of curved channels includes a first curved channel and a second curved channel, and wherein at least two abrupt portions are intermediate the first curved channel and the second curved channel.

22. The planar micromixer as claimed in claim 21, wherein said first curved channel curves in a first direction and said second curved channel curves in a second direction that is opposite the first direction.

23. The planar micromixer as claimed in claim 21, wherein said first curved channel curves in a first direction and said second curved channel curves in the same first direction.
